(19) United States
(12) Patent Application Publication
(10) Pub. No.: US 2026/0082509 A1
(43) Pub. Date: Mar. 19, 2026

(54) LIQUID COOLING DEVICE

(71) Applicant: DELUXE POINT LIMITED (Taiwan Branch), New Taipei City (TW)

(72) Inventors: Yu-Hung Chang Zhang, New Taipei City (TW); Yun-Ting Liu, New Taipei City (TW)

(21) Appl. No.: 19/290,664

(22) Filed: Aug. 5, 2025

(30) Foreign Application Priority Data
Sep. 18, 2024 (TW) 113135236

(51) Int. Cl. H05K 7/20

(52) U.S. Cl. CPC H05K 7/20263; H05K 7/20272

(57) ABSTRACT

A liquid cooling device includes multiple flat tube assemblies parallel to one another, and each of the two of the flat tube assemblies have a heat dissipation assembly disposed in between. Each flat tube assembly includes: a first flat tube, configured to circulate a hot liquid; a second flat tube, configured to circulate a cold liquid; a liquid return assembly, in fluid communication with the first tube and the second tube to circulate the hot liquid and the cold liquid; and a first inducing assembly in fluid communication with the first flat tube to input the hot liquid, and a second inducing assembly in fluid communication with the second flat tube to output the cold liquid. The first and second flat tubes in the flat tube assembly are arranged separately, and the first tubes are closer to an air exhaust end of the liquid cooling device than the second flat tubes.

### BACKGROUND OF THE INVENTION

### Field of the Invention

The present invention relates to a liquid cooling device, and more particularly to a liquid cooling device for an operation apparatus such as a computer or a server.

### Description of the Related Art

A common liquid cooling device for a computer usually consists of a hot liquid chamber and a cold liquid chamber. A hot liquid in the hot liquid chamber flows to cooling fins via an inducing tube, undergoes heat exchange by means of being closely fitted with the cooling fins, and then returns to the cold liquid chamber for cooling. However, a conventional device contains an obvious design defect; that is, separation between a cold water stream and a hot water stream is not effective enough. More specifically, because the cold water stream is easily heated by residual heat energy in the cooling fins after coming into contact with the cooling fins as the temperature of the cooling fins is greater than the temperature of cold water, the temperature of the cold water stream rises and the overall heat dissipation efficiency is thus reduced.

The issue of heat conduction between hot and cold-water streams results in a failure of fully practicing a cooling function, and eventually affects the performance of a cooling system.

### SUMMARY OF THE INVENTION

A solution for improving a design for separating hot and cold water streams for such type of cooling devices and optimizing a heat dissipation path of a cold water stream is the key to enhance heat dissipation efficiency.

In some embodiments, the present disclosure provides methods and structures to effectively isolate a cold liquid and a hot liquid to thereby enhance the overall heat dissipation efficiency. In a structure of the present disclosure, a cold liquid and a hot liquid are located in different tubes during a circulation process to prevent the two from mixing with each other, wherein a tube for the hot liquid is close to an air exhaust end to quickly discharge heat energy via the air exhaust end after the hot liquid passes through cooling fins. In the present disclosure, heat energy of the hot liquid can be taken away within a minimal period to reduce the residence time of the hot liquid in a system, hence further enhancing the heat dissipation efficiency.

To achieve the purpose above, the present disclosure provides a liquid cooling device including a plurality of flat tube assemblies. The flat tube assemblies are parallel to one another, and two of the flat tube assemblies have a heat dissipation assembly disposed in between. Each of the flat tube assemblies includes a first flat tube configured to circulate a hot liquid and a second flat tube configured to circulate a cold liquid; a liquid return assembly, disposed on one side of the plurality of flat tube assemblies, and being in fluid communication with the first flat tube and the second flat tube to circulate the hot liquid and the cold liquid; and a first inducing assembly and a second inducing assembly, disposed on one other side of the plurality of flat tube assemblies relative to the liquid return assembly, the first inducing assembly in fluid communication with the first flat tube to input the hot liquid, and the second inducing assembly in fluid communication with the second flat tube to output the cold liquid; wherein the first flat tube and the second flat tube in the flat tube assembly are arranged separately, and the plurality of first flat tubes are closer to an air exhaust end of the liquid cooling device than the plurality of second flat tubes.

In one embodiment, the heat dissipation assembly is a plurality of cooling fins, which are connected to the flat tube assemblies to define an air inlet end and the air exhaust end of the liquid cooling device.

In one embodiment, the first inducing assembly and the second inducing assembly are not in direct fluid communication with each other.

To achieve the purpose above, the present disclosure provides a liquid cooling device including a plurality of flat tube assemblies, which are parallel to one another. Each of the flat tube assemblies includes: a first flat tube, configured to circulate a hot liquid; a second flat tube, configured to circulate a cold liquid; a liquid return assembly, disposed on one side of the plurality of flat tube assemblies, and being in fluid communication with the first flat tube and the second flat tube to circulate the hot liquid and the cold liquid; and a first inducing assembly and a second inducing assembly, disposed on one other side of the plurality of flat tube assemblies relative to the liquid return assembly, the first inducing assembly in fluid communication with the first flat tube to input the hot liquid, and the second inducing assembly in fluid communication with the second flat tube to output the cold liquid; wherein the first flat tube and the second flat tube in the flat tube assembly are arranged separately, two adjacent ones of the plurality of first flat tubes have a first heat dissipation assembly in between, two adjacent ones of the plurality of second flat tubes have a second heat dissipation assembly in between, and the first heat dissipation assembly and the second heat dissipation assembly are separated.

In one embodiment, the first heat dissipation assembly and the second heat dissipation assembly are a plurality of cooling fins. The liquid cooling device has an air inlet end and an air exhaust end, and the first flat tube and the first heat dissipation assembly are configured to be closer to the air exhaust end than the second flat tube and the second heat dissipation assembly.

In one embodiment, an arrangement of the first flat tube and the first heat dissipation assembly is symmetrical to an arrangement of the second flat tube and the second heat dissipation assembly.

To achieve the purpose above, the present disclosure provides an operation apparatus including: the liquid cooling device above; and a cooling liquid circulation system, being in fluid communication with the first inducing assembly and the second inducing assembly, for the liquid cooling device to process a cooling liquid from the cooling liquid circulation system.

### BRIEF DESCRIPTION OF THE DRAWINGS

FIG. 1 is a perspective diagram of a liquid cooling device of the present invention;

FIG. 2 is an exploded diagram of a liquid cooling device of the present invention; and

FIG. 3 is a schematic diagram of heat dissipation of a liquid cooling device of the present invention.

### DETAILED DESCRIPTION OF THE EMBODIMENTS

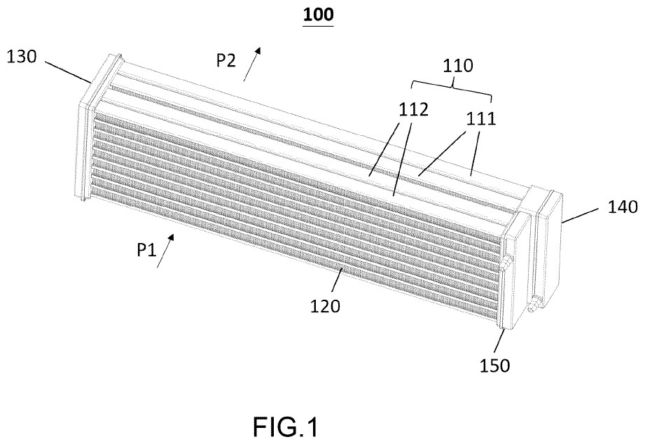

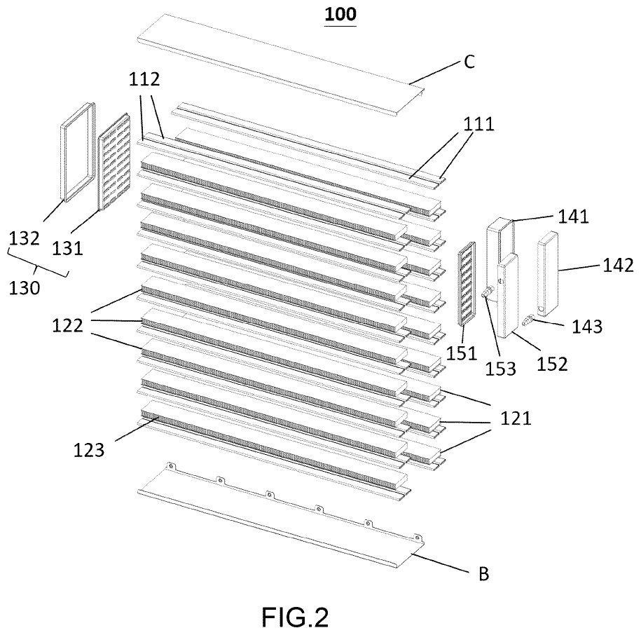

As shown in FIG. 1 and FIG. 2, a liquid cooling device 100 of the present disclosure includes a plurality of flat tube assemblies 110, a plurality of heat dissipation assemblies 120, a liquid return assembly 130, a first inducing assembly 140 and a second inducing assembly 150. The flat tube assemblies 110 are parallel to one another, and two of the flat tube assemblies 110 have one heat dissipation assembly 120 disposed in between. Each flat tube assemblies 110 includes a first flat tube 111 and a second flat tube 112. The first flat tube 111 is configured to circulate a hot liquid, and the second flat tube 112 is configured to circulate a cold liquid. The liquid return assembly 130 is disposed on one side of the plurality of flat tube assemblies 110 and is in fluid communication with the first flat tube 111 and the second flat tube 112 to circulate the hot liquid and the cold liquid. The first inducing assembly 140 and the second inducing assembly 150 are disposed on the other side of the plurality of flat tube assemblies 110 relative to the liquid return assembly 130. The first inducing assembly 140 is in fluid communication with the first flat tube 111 to input the hot liquid, and the second inducing assembly 150 is in fluid communication with the second flat tube 112 to output the cold liquid from the second flat tube 112. The first flat tube 111 and the second flat tube 112 in the flat tube assembly 110 are arranged separately, and the first flat tube 111 and the second flat tube 112 do not come into contact with each other and have a gap in between. In a specific embodiment of the present disclosure, the liquid cooling device 100 of the present disclosure is a cooling device installed in a server or a computer to dissipate heat of an operation apparatus such as a processor. The liquid cooling device 100 is in fluid communication with a cooling liquid circulation system (not shown). More specifically, the cooling liquid circulation system is in fluid communication with the first inducing assembly 140 and the second inducing assembly 150 of the liquid cooling device 100, for the liquid cooling device 100 to process a cooling liquid from the cooling liquid circulation system.

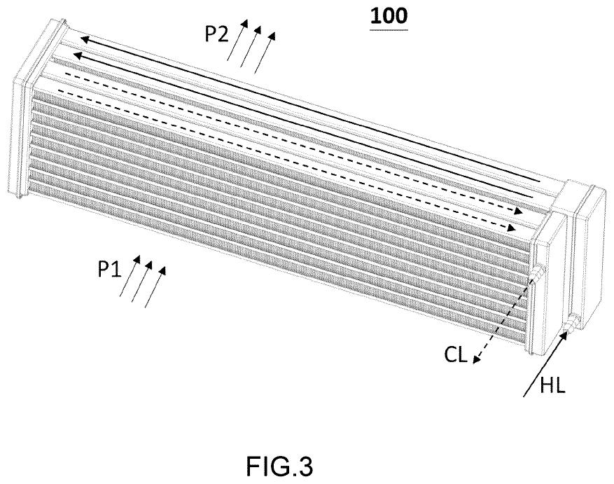

More specifically, the liquid cooling device 100 of the present disclosure includes an upper lid C and a lower lid B. The upper lid C, the lower lid B, the liquid return assembly 130, the first inducing assembly 140 and the second inducing assembly 150 jointly define an accommodating space, which defines the numbers and sizes of the flat tube assemblies 110 and the heat dissipation assemblies 120. The upper lid C and the lower lid B are made of an aluminum alloy with better heat dissipation and are configured with the plurality of flat tube assemblies 110 arranged in parallel in between. The first flat tube 111 and the second flat tube 112 of the flat tube assembly 110 are elongated flat liquid flow tubes extending horizontally. The first flat tube 111 is connected to the liquid return assembly 130 at one end and connected to the first inducing assembly 140 at the other end by methods of, for example, welding. The second flat tube 112 is connected to the liquid return assembly 130 at one end and connected to the second inducing assembly 150 at the other end similarly by methods of, for example, welding. By methods of welding, the hot liquid or the cold liquid in the course of flowing is prevented from leaking from joints of the assemblies above. Moreover, any connecting methods capable of overcoming thermal expansion and contraction and preventing the hot liquid and the cold liquid from leaking is also encompassed within the scope of the present disclosure. In a preferred embodiment of the present disclosure, the first flat tube 111 and the second flat tube 112 are composed of two separated flat tubes respectively, and the plurality of first flat tubes 111 are disposed closer to an air exhaust end P2 (referring to FIG. 3) of the liquid cooling device 100 than the plurality of second flat tubes 112. In an embodiment of the present disclosure, each of the first flat tube 111 and the second flat tube 112 includes two elongated flat liquid flow tubes.

The heat dissipation assembly 120 includes a first heat dissipation assembly 121 and a second heat dissipation assembly 122. Each of the first heat dissipation assembly 121 and the second heat dissipation assembly 122 comprising a plurality of cooling fins 123 arranged at intervals. The cooling fins 123 are parallel to one another and are perpendicular to the flat tube assembly 110 and connected between two flat tube assemblies 110. More specifically, an arrangement direction of the cooling fins 123 is perpendicular to a flow direction of the hot liquid in the first flat tube 111 or perpendicular to a flow direction of the cold liquid in the second flat tube 112, and the arrangement direction of the cooling fins 123 further defines an air inlet end P1 and the air exhaust end P2 of the liquid cooling device 100 (referring to FIG. 3). Moreover, when observing from a top view direction, the heat dissipating area of the first heat dissipation assembly 121 is substantially equal to the heat dissipating area of the first flat tube 111, and the heat dissipating area of the second heat dissipation assembly 122 is substantially equal to the heat dissipating area of the second flat tube 112. In a specific embodiment of the present disclosure, the cooling fins 123 can be an integrally formed and arranged between two flat tube assemblies 110, or the cooling fins 123 of the first heat dissipation assembly 121 are arranged between two first flat tubes 112, and the cooling fins 123 of the second heat dissipation assembly 122 are arranged between two second flat tubes 112. That is, the first heat dissipation assembly 121 and the second heat dissipation assembly 122 are arranged separately, and the first heat dissipation assembly 121 is closer to the air exhaust end P2 than the second heat dissipation assembly 122 (referring to FIG. 3). In a specific embodiment of the present disclosure, directions of airflows of the air inlet end P1 and the air exhaust end P2 are defined by circulation airflows provided by a fan or in a casing.

The liquid return assembly 130 includes a liquid return box body 131 and a liquid return box lid 132. The liquid return box body 131 has a plurality of rows of insert holes individually connected to the first flat tube 111 and the second flat tube 112. The liquid return box lid 132 is arranged on the liquid return box body 131, and the two jointly define a path for a fluid.

The first inducing assembly 140 includes a first chamber body 141, a first chamber lid 142 and a first connector 143. The first chamber body 141 is connected to one end of the first flat tube 111 relative to the liquid return assembly 130, the first chamber lid 142 is arranged on the first chamber body 141 and the two define a path for the hot liquid, and the first connector 143 is arranged on the first chamber body 141 to input the hot liquid into the first inducing assembly 140. Similarly, the second inducing assembly 150 includes a second chamber body 151, a second chamber lid 152 and a second connector 153. The second chamber body 151 is connected to one end of the second flat tube 112 relative to the liquid return assembly 130, the second chamber lid 152 is arranged on the second chamber body 151 and the two define a path for the cold liquid, and the second connector 153 is arranged on the second chamber body 151 to discharge the cold liquid from the second inducing assembly 150. In the present disclosure, the first chamber body 141 also has a plurality of rows of insert holes arranged correspondingly to the plurality of rows of insert holes of the liquid return box body 131 (the right of the drawing), so that the first flat tube 111 is connected between the liquid return box body 131 and the first chamber body 141. Similarly, the second chamber body 151 also has a plurality of rows of insert holes arranged correspondingly to the plurality of rows of insert holes of the liquid return box body 131 (the left of the drawing), so that the second flat tube 112 is connected between the liquid return box body 131 and the second chamber body 151. The arrangement of the first flat tube 111 and the first heat dissipation assembly 121 is symmetrical to the arrangement of the second flat tube 112 and the second heat dissipation assembly 122; that is, the two arrangements are consistent in number, structure and position. Moreover, the first inducing assembly 140 and the second inducing assembly 150 are not in fluid communication with each other and do not come into contact with each other.

Refer to FIG. 1 to FIG. 3 for specific methods for heat dissipation of the liquid cooling device 100 of the present application. First, a hot liquid HL (the solid-line arrow in FIG. 3) formed by absorbing heat energy of a processor flows from the first connector 143 to an interior of the first inducing assembly 140, and then flows to the liquid return assembly 130 through the first flat tube 111. When the hot liquid HL flows through a path of the first flat tube 111, heat energy of the hot liquid HL is transmitted by heat conduction to the first heat dissipation assembly 121, and then the first heat dissipation assembly 121 discharges the heat energy from the air exhaust end P2 by heat convection. The hot liquid HL having undergone heat dissipation forms a cold liquid CL (the dotted-line arrow in FIG. 3), which is discharged from the first flat tube 111 to the liquid return assembly 130. The cold liquid CL then flows through the second flat tube 112 to the interior of the second inducing assembly 150. When the cold liquid CL flows through a path of the second flat tube 112, similar to heat dissipation performed by the first heat dissipation assembly 121, heat energy of the cold liquid CL is discharged from the second heat dissipation assembly 122. The cold liquid CL having undergone heat dissipation eventually flows out from the second connector 153 of the second inducing assembly 150, and accordingly flows to the computer processor to absorb heat of the computer processor to reduce the operating temperature of the computer processor, and the hot liquid HL is formed and again flows to the interior of the first inducing assembly 140, hence forming water circulation. In the present disclosure, the cold liquid CL is defined as a fluid having a lower temperature than the hot liquid HL and includes the hot liquid HL having undergone heat dissipation and the cold liquid CL having undergone heat dissipation.

Overall, the liquid cooling device of the present disclosure achieves the following effects. First, the present disclosure capable of effectively isolate a cold liquid and a hot liquid to thereby enhance the overall heat dissipation efficiency. More specifically, by separating the first flat tube and the second flat tube, the cold liquid and the hot liquid are located in different tubes and do not come into contact with each other during a circulation process, preventing the two from mixing with each other. Thus, this structure can prevent heat energy of the hot liquid of the first flat tube from transferring to the cold liquid of the second flat tube and prevent the cooled cold liquid from being heated again, thereby enhancing the overall cooling efficiency.

Secondly, by respectively arranging the cooling fins at the first flat tube and the second flat tube separated from each other, the cooling fins of the first flat tube and the second flat tube do not come into contact with each other. Thus, this structure can prevent heat energy of the hot liquid of the first flat tube from transferring from the cooling fins to the cold liquid of the second flat tube, and at the same time stabilize the flat tubes by the cooling fins to reinforce the structural strength of heat dissipation tubes.

Thirdly, the first flat tube is arranged to be close to the air exhaust end. As such, once heat energy of the hot liquid is discharged by the cooling fins, the heat energy can be discharged via the air exhaust end. Thus, this structure can ensure that heat energy of the hot liquid is taken away within a minimal period, so as to reduce the residence time of the hot liquid in a system without any resulting heat convection affecting the second flat tube and the cooling fins arranged at the second flat tube, hence further enhancing the heat dissipation efficiency.

What is claimed is:

1. A liquid cooling device, comprising:
a plurality of flat tube assemblies, the flat tube assemblies being parallel to one another, two of the flat tube assemblies having a heat dissipation assembly disposed in between, each of the flat tube assemblies comprising:
a first flat tube, configured to circulate a hot liquid;
a second flat tube, configured to circulate a cold liquid;
a liquid return assembly, disposed on one side of the plurality of flat tube assemblies, and being in fluid communication with the first flat tube and the second flat tube to circulate the hot liquid and the cold liquid; and
a first inducing assembly and a second inducing assembly, disposed on one other side of the plurality of flat tube assemblies relative to the liquid return assembly, the first inducing assembly being in fluid communication with the first flat tube to input the hot liquid, and the second inducing assembly being in fluid communication with the second flat tube to output the cold liquid;
wherein the first flat tube and the second flat tube in the flat tube assembly are arranged thermally separated.

2. The liquid cooling device according to claim 1, wherein the heat dissipation assembly comprises a plurality of cooling fins, which are connected to the flat tube assemblies to define an air inlet end and the air exhaust end of the liquid cooling device.

3. The liquid cooling device according to claim 1, wherein the first inducing assembly and the second inducing assembly are not in direct fluid communication with each other.

4. The liquid cooling device according to claim 1, wherein the plurality of first flat tubes are closer to an air exhaust end of the liquid cooling device than the plurality of second flat tubes.

5. A liquid cooling device, comprising:
a plurality of flat tube assemblies, the flat tube assemblies being parallel to one another, each of the flat tube assemblies comprising:
a first flat tube, configured to circulate a hot liquid;
a second flat tube, configured to circulate a cold liquid;
a liquid return assembly, disposed on one side of the plurality of flat tube assemblies, and being in fluid communication with the first flat tube and the second flat tube to circulate the hot liquid and the cold liquid; and
a first inducing assembly and a second inducing assembly, disposed on one other side of the plurality of flat tube assemblies relative to the liquid return assembly, the first inducing assembly being in fluid communication with the first flat tube to input the hot liquid, and the second inducing assembly being in fluid communication with the second flat tube to output the cold liquid;
wherein the first flat tube and the second flat tube in the flat tube assembly are arranged separately, two adjacent ones of the plurality of first flat tubes have a first heat dissipation assembly in between, and two adjacent ones of the plurality of second flat tubes have a second heat dissipation assembly in between, and the first heat dissipation assembly and the second heat dissipation assembly are separated.

6. The liquid cooling device according to claim 5, wherein the first heat dissipation assembly and the second heat dissipation assembly comprise a plurality of cooling fins.

7. The liquid cooling device according to claim 5, wherein the liquid cooling device has an air inlet end and an air exhaust end.

8. The liquid cooling device according to claim 7, wherein the first flat tube and the first heat dissipation assembly are configured to be closer to the air exhaust end than the second flat tube and the second heat dissipation assembly.

9. The liquid cooling device according to claim 5, wherein an arrangement of the first flat tube and the first heat dissipation assembly is symmetrical to an arrangement of the second flat tube and the second heat dissipation assembly.

10. A method of cooling a computing device comprising:
a) receiving hot fluid from a computing device at a first portion of a liquid cooling device;
b) cooling the hot fluid by circulating the hot fluid within the first portion of the liquid cooling device so that the hot fluid becomes a cold fluid, wherein the first portion comprises first flat tubes having a first set of heat dissipation structures disposed in between the first flat tubes;
c) receiving the cold fluid at a second portion of the liquid cooling device and circulating the cold fluid within the second portion of the liquid cooling device to further cool the cold fluid and forming a further cooled cold fluid; and
d) outputting the further cooled cold fluid.

11. The method of claim 10, wherein the second portion comprises second flat tubes having a second set of heat dissipation structures disposed in between the second flat tubes.

12. The method of claim 10, wherein the first flat tubes are parallel to each other.

13. The method of claim 10, wherein the second flat tubes are parallel to each other.

14. The method of claim 10, wherein the first portion and the second portion are parallel to each other and in fluid communication through a fluid return perpendicular to the first portion and the second portion of the liquid cooling device.

15. The method of claim 10, further comprising receiving a cooling air from an air cooling side of the second portion of the liquid cooling device.

16. The method of claim 10, wherein the first set of the heat dissipation structures comprise a first set of cooling fins.

17. The method of claim 16, wherein the first set of the cooling fins are perpendicular to the first flat tubes.

18. The method of claim 16, wherein the first set of the cooling fins are evenly distributed throughout a body of a first heat dissipation assembly.

19. The method of claim 16, wherein the first heat dissipation assembly is parallel to the first flat tubes.

20. The method of claim 10, wherein the first portion and the second portion are spatially separated and only fluidly coupled with one end of the first and the second portion.
